(19) United States
(12) Patent Application Publication
(10) Pub. No.: US 2024/0388270 A1
(43) Pub. Date: Nov. 21, 2024

(54) AMPLITUDE AND PHASE ERROR CORRECTION IN A WIRELESS COMMUNICATION CIRCUIT

(71) Applicant: Qorvo US, Inc., Greensboro, NC (US)

(72) Inventor: Nadim Khlat, Cugnaux (FR)

(21) Appl. No.: 18/394,376

(22) Filed: Dec. 22, 2023

Related U.S. Application Data
(60) Provisional application No. 63/466,801, filed on May 16, 2023.
(60) Provisional application No. 63/480,785, filed on Jan. 20, 2023.

(51) Int. Cl. H03G 3/30; H03F 3/24; H03G 5/16

(52) U.S. Cl. CPC H03G 3/3042; H03F 3/245; H03G 5/165; H03G 2201/103; H03G 2201/307

(57) ABSTRACT

Amplitude and phase error correction in a transceiver circuit is provided. In embodiments disclosed herein, a transceiver circuit is configured to equalize an input vector to thereby correct amplitude-amplitude (AM-AM) and amplitude-phase (AM-PM) errors across a modulation bandwidth of the wireless communication circuit. Unlike conventional methods where complicated memory digital predistortion (mDPD) coefficients must be defined and calibrated for each modulation frequency within the modulation bandwidth, the transceiver circuit is configured herein to eliminate modulation frequency dependency of the AM-AM and AM-PM errors. As a result, it is possible to correct the AM-AM and AM-PM errors across the modulation bandwidth with reduced complexity to thereby improve efficiency and linearity of the wireless communication circuit.

### RELATED APPLICATIONS

This application claims the benefit of U.S. provisional patent application Ser. No. 63/480,785, filed on Jan. 20, 2023, and U.S. provisional patent application Ser. No. 63/466,801, filed on May 16, 2023, the disclosures of which are hereby incorporated herein by reference in their entireties.

### FIELD OF THE DISCLOSURE

The technology of the disclosure relates generally to correcting amplitude-amplitude (AM-AM) and amplitude-phase (AM-PM) errors in a wireless communication circuit.

### BACKGROUND

Mobile communication devices have become increasingly common in current society for providing wireless communication services. The prevalence of these mobile communication devices is driven in part by the many functions that are now enabled on such devices. Increased processing capability in such devices means that mobile communication devices have evolved from being pure communication tools into sophisticated mobile multimedia centers that enable enhanced user experiences.

The redefined user experience relies on higher data rates offered by advanced fifth generation (5G) and 5G new radio (5G-NR) technologies, which typically transmit and receive radio frequency (RF) signals in millimeter wave spectrums. Given that the RF signals are more susceptible to attenuation and interference in the millimeter wave spectrums, the RF signals are typically amplified by state-of-the-art power amplifiers to help boost the RF signals to a higher power before transmission.

In a typical wireless communication circuit, a transceiver circuit is configured to generate an RF signal, a power management circuit is configured to generate a modulated voltage, a power amplifier circuit is configured to amplify the RF signal based on the modulated voltage, and an antenna circuit is configured to transmit the RF signal in one or more transmission frequencies. The power amplifier circuit can be further coupled to the antenna circuit via an RF frontend circuit (e.g., filter, switches, etc.). Notably, an output reflection coefficient (e.g., S₂₂) of the power amplifier circuit can interact with an input reflection coefficient (e.g., S₁₁) of the RF frontend circuit to cause a group delay in the RF signal to potentially create amplitude-amplitude (AM-AM) and amplitude-phase (AM-PM) errors in the modulated voltage. As such, it is desirable to correct the AM-AM and the AM-PM errors in all of the transmission frequencies to help prevent undesired amplitude distortion, particularly when the RF signal is modulated across a wide modulation bandwidth (e.g., 200 MHz).

### SUMMARY

Embodiments of the disclosure relate to amplitude and phase error correction in a wireless communication circuit. The wireless communication circuit includes a transceiver circuit, a power management integrated circuit (PMIC), and a power amplifier circuit(s). The transceiver circuit generates a radio frequency (RF) signal(s) from an input vector, the PMIC generates a modulated voltage, and the power amplifier circuit(s) amplifies the RF signal(s) based on the modulated voltage. When the power amplifier circuit(s) is coupled to an RF frontend circuit (e.g., filter/multiplexer), an output reflection coefficient (e.g., S₂₂) of the power amplifier circuit(s) can interact with an input reflection coefficient (e.g., S₁₁) of the RF frontend circuit to create a voltage distortion filter on an output stage of the power amplifier circuit(s), which can cause unwanted amplitude-amplitude (AM-AM) and amplitude-phase errors across a modulation bandwidth of the wireless communication circuit.

In this regard, in embodiments disclosed herein, the transceiver circuit is configured to equalize the input vector to thereby correct the AM-AM and AM-PM errors across the modulation bandwidth. Unlike conventional methods where complicated memory digital predistortion (mDPD) coefficients must be defined and calibrated for each modulation frequency within the modulation bandwidth, the transceiver circuit is configured herein to eliminate modulation frequency dependency of the AM-AM and AM-PM errors. As a result, it is possible to correct the AM-AM and AM-PM error across the modulation bandwidth with reduced complexity to thereby improve efficiency and linearity of the wireless communication circuit.

In one aspect, a transceiver circuit is provided. The transceiver circuit includes a frequency equalization circuit. The frequency equalization circuit is configured to apply a frequency equalization filter to an input vector to thereby generate a frequency-equalized input vector having a respective linearized gain error and a respective linearized phase error in each of multiple modulation frequencies. The transceiver circuit also includes a gain error correction circuit. The gain error correction circuit is configured to determine a linearized gain error correction term in a selected modulation frequency among the multiple modulation frequencies based on the respective linearized gain error in a reference modulation frequency among the multiple modulation frequencies. The transceiver circuit also includes a phase error correction circuit. The phase error correction circuit is configured to determine a linearized phase error correction term in the selected modulation frequency based on the respective linearized phase error in the reference modulation frequency. The transceiver circuit also includes an amplitude-phase correction circuit. The amplitude-phase correction circuit is configured to add the linearized gain error correction term and the linearized phase error correction term to the frequency-equalized input vector to thereby generate an amplitude-phase corrected input vector in the selected modulation frequency.

In another aspect, a wireless device is provided. The wireless device includes a transceiver circuit. The transceiver circuit includes a frequency equalization circuit. The frequency equalization circuit is configured to apply a frequency equalization filter to an input vector to thereby generate a frequency-equalized input vector having a respective linearized gain error and a respective linearized phase error in each of multiple modulation frequencies. The transceiver circuit also includes a gain error correction circuit. The gain error correction circuit is configured to determine a linearized gain error correction term in a selected modulation frequency among the multiple modulation frequencies based on the respective linearized gain error in a reference modulation frequency among the multiple modulation frequencies. The transceiver circuit also includes a phase error correction circuit. The phase error correction circuit is configured to determine a linearized phase error correction term in the selected modulation frequency based on the respective linearized phase error in the reference modulation frequency. The transceiver circuit also includes an amplitude-phase correction circuit. The amplitude-phase correction circuit is configured to add the linearized gain error correction term and the linearized phase error correction term to the frequency-equalized input vector to thereby generate an amplitude-phase corrected input vector in the selected modulation frequency.

In another aspect, a method for correcting amplitude and phase errors in a wireless communication circuit is provided. The method includes applying a frequency equalization filter to an input vector to thereby generate a frequency-equalized input vector having a respective linearized gain error and a respective linearized phase error in each of multiple modulation frequencies. The method also includes determining a linearized gain error correction term in a selected modulation frequency among the multiple modulation frequencies based on the respective linearized gain error in a reference modulation frequency among the multiple modulation frequencies. The method also includes determining a linearized phase error correction term in the selected modulation frequency based on the respective linearized phase error in the reference modulation frequency. The method also includes adding the linearized gain error correction term and the linearized phase error correction term to the frequency-equalized input vector to thereby generate an amplitude-phase corrected input vector in the selected modulation frequency.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 is a schematic diagram of an exemplary wireless communication circuit, wherein an unwanted voltage distortion filter may cause amplitude-amplitude (AM-AM) and amplitude-phase (AM-PM) errors in a power amplifier circuit when the power amplifier circuit is coupled to a radio frequency (RF) frontend circuit;

FIG. 2 is a graphic diagram illustrating a distribution of the AM-AM error across a modulation bandwidth of the wireless communication circuit of FIG. 1;

FIG. 3 is a graphic diagram illustrating a distribution of the AM-PM error across the modulation bandwidth of the wireless communication circuit of FIG. 1;

FIG. 4 is a graphic diagram illustrating a low-complexity AM-AM error correction scheme that can effectively correct the AM-AM error in the wireless communication circuit of FIG. 1;

FIG. 5 is a graphic diagram illustrating a low-complexity AM-PM error correction scheme that can effectively correct the AM-PM error in the wireless communication circuit of FIG. 1;

FIG. 6 is a schematic diagram of an exemplary transceiver circuit configured according to embodiments of the present disclosure to correct the AM-AM and AM-PM errors in the wireless communication circuit of FIG. 1 based on the low-complexity AM-AM error correction scheme illustrated in FIG. 4 and the low-complexity AM-PM error correction scheme illustrated in FIG. 5;

FIG. 7 is a schematic diagram of an exemplary gain error correction circuit in the transceiver circuit of FIG. 6;

FIG. 8 is a schematic diagram of an exemplary phase error correction circuit in the transceiver circuit of FIG. 6;

FIG. 9 is a schematic diagram of an exemplary user element wherein the transceiver circuit of FIG. 6 can be provided; and

FIG. 10 is a flowchart of an exemplary process for correcting amplitude and phase errors in a wireless communication circuit, such as the user element of FIG. 9.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments of the disclosure relate to amplitude and phase error correction in a wireless communication circuit. The wireless communication circuit includes a transceiver circuit, a power management integrated circuit (PMIC), and a power amplifier circuit(s). The transceiver circuit generates a radio frequency (RF) signal(s) from an input vector, the PMIC generates a modulated voltage, and the power amplifier circuit(s) amplifies the RF signal(s) based on the modulated voltage. When the power amplifier circuit(s) is coupled to an RF frontend circuit (e.g., filter/multiplexer), an output reflection coefficient (e.g., S₂₂) of the power amplifier circuit(s) can interact with an input reflection coefficient (e.g., S₁₁) of the RF frontend circuit to create a voltage distortion filter on an output stage of the power amplifier circuit(s), which can cause unwanted amplitude-amplitude (AM-AM) and amplitude-phase errors across a modulation bandwidth of the wireless communication circuit.

In this regard, in embodiments disclosed herein, the transceiver circuit is configured to equalize the input vector to thereby correct the AM-AM and AM-PM errors across the modulation bandwidth. Unlike conventional methods where complicated memory digital predistortion (mDPD) coefficients must be defined and calibrated for each modulation frequency within the modulation bandwidth, the transceiver circuit is configured herein to eliminate modulation frequency dependency of the AM-AM and AM-PM errors. As a result, it is possible to correct the AM-AM and AM-PM errors across the modulation bandwidth with reduced complexity to thereby improve efficiency and linearity of the wireless communication circuit.

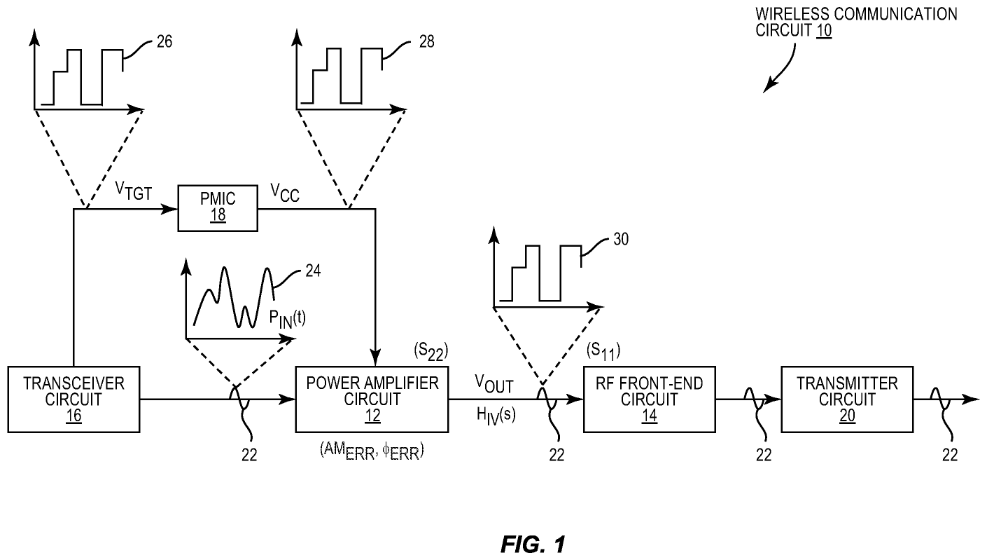

FIG. 1 is a schematic diagram of an exemplary wireless communication circuit 10 (e.g., a wireless device), wherein an unwanted voltage distortion filter H_{IV}(s) may cause AM-AM and AM-PM errors in a power amplifier circuit 12 when the power amplifier circuit 12 is coupled to a radio frequency (RF) frontend circuit 14. Notably, in the unwanted voltage distortion filter H_{IV}(s), “s” is a notation of Laplace transform. The wireless communication circuit 10 includes a transceiver circuit 16, a power management integrated circuit (PMIC) 18, and a transmitter circuit 20, which can include an antenna(s) (not shown) as an example.

The transceiver circuit 16 is configured to generate an RF signal 22 having a time-variant input power P_{IN}(t) that corresponds to a time-variant voltage envelope 24 and provides the RF signal 22 to the power amplifier circuit 12. The transceiver circuit 16 is also configured to generate a time-variant target voltage VTGT, which is associated with a time-variant target voltage envelope 26 that tracks the time-variant voltage envelope 24 of the RF signal 22. The PMIC 18 is configured to generate a modulated voltage V_{CC} having a time-variant modulated voltage envelope 28 that tracks the time-variant target voltage envelope 26 of the time-variant target voltage VTGT and provides the modulated voltage V_{CC} to the power amplifier circuit 12. In context of the present disclosure, the modulated voltage V_{CC} is an average power tracking (APT) voltage.

The power amplifier circuit 12 is configured to amplify the RF signal 22 based on the modulated voltage V_{CC} to a time-variant output voltage VOUT associated with a time-variant output voltage envelope 30. The power amplifier circuit 12 then provides the amplified RF signal 22 to the RF frontend circuit 14. The RF frontend circuit 14 may be a filter circuit that performs further frequency filtering on the amplified RF signal 22 before providing the amplified RF signal 22 to the transmitter circuit 20 for transmission.

When the power amplifier circuit 12 is coupled to the RF frontend circuit 14, the unwanted voltage distortion filter H_{IV}(s) can cause frequency-dependent AM-AM and AM-PM errors across all modulation frequencies across the modulation bandwidth. For a detailed analysis as to how the unwanted voltage distortion filter H_{IV}(s) can be created by the coupling of the power amplifier circuit 12 and the RF frontend circuit 14, please refer to U.S. patent application Ser. No. 17/939,350, entitled “PHASE AND AMPLITUDE ERROR CORRECTION IN A TRANSMISSION CIRCUIT.”

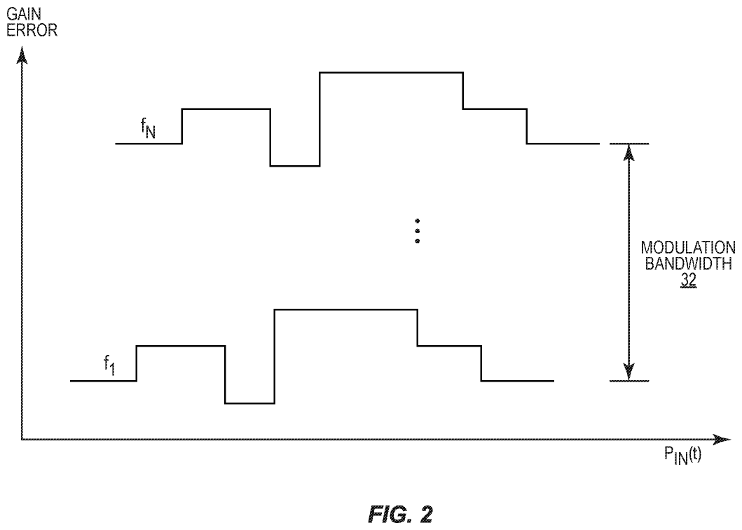

FIG. 2 is a graphic diagram illustrating a distribution of the AM-AM error across an entire modulation bandwidth 32 of the wireless communication circuit 10 of FIG. 1. The modulation bandwidth 32 includes multiple modulation frequencies f₁-f_{N}. Each of the modulation frequencies f₁-f_{N} corresponds to a respective time-variant gain error that is dependent on the time-variant input power P_{IN}(t). In other words, the gain error has a dependency on both the modulation frequencies f₁-f_{N} and the time-variant input power P_{IN}(t).

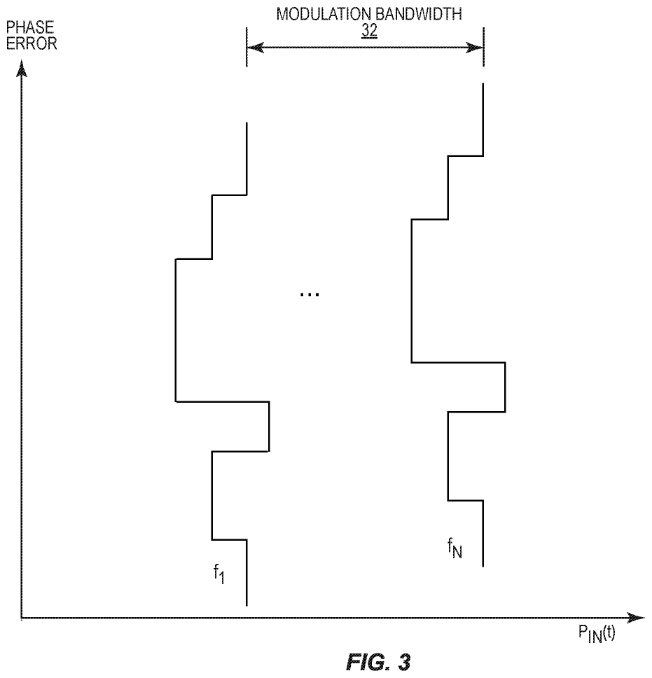

FIG. 3 is a graphic diagram illustrating a distribution of the AM-PM error across the entire modulation bandwidth 32 of the wireless communication circuit 10 of FIG. 1. The modulation bandwidth 32 includes multiple modulation frequencies f₁-f_{N}. Each of the modulation frequencies f₁-f_{N} corresponds to a respective time-variant phase error that is dependent on the time-variant input power P_{IN}(t). In other words, the phase error has a dependency on both the modulation frequencies f₁-f_{N} and the time-variant input power P_{IN}(t).

A conventional approach for correcting such gain and phase errors is to employ a memory digital predistortion (mDPD) circuit in the transceiver circuit 16 to inject a gain error correction term into the RF signal 22. However, given the frequency and power dependency of the gain error, the mDPD circuit must define and calibrate a respective set of complex coefficients for each of the modulation frequencies f₁-f_{N}. Notably, to operate in a fifth generation (5G) or a 5G new-radio (5G-NR) system, the wireless communication circuit 10 often needs to support a wide modulation bandwidth (e.g., >200 MHz). As such, a number of the modulation frequencies f₁-f_{N} can increase significantly, thus leading to a significantly increased complexity with respect to implementation and calibration of the mDPD coefficients. Hence, it is desirable to enhance the wireless communication circuit 10 based on a low-complexity AM-AM and AM-PM error correction scheme to effectively correct the gain and phase errors across the entire modulation bandwidth 32.

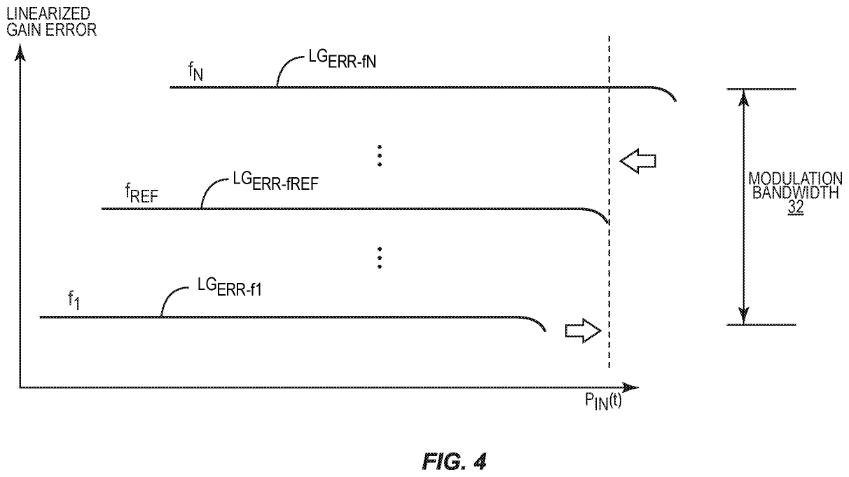

FIG. 4 is a graphic diagram illustrating a low-complexity AM-AM error correction scheme that can effectively correct the AM-AM error in the wireless communication circuit 10 of FIG. 1. Herein, the low-complexity AM-AM correction scheme is able to reduce complexity associated with AM-AM error correction by eliminating modulation frequency dependency of the gain error.

First of all, the gain error associated with each of the modulation frequencies f₁-f_{N} is linearized with respect to the time-variant input power P_{IN}(t) to create a respective one of multiple linearized gain errors LG_{ERR-f1}-LG_{ERR-fN}. As shown in FIG. 4, the linearized gain errors LG_{ERR-f1}-LG_{ERR-fN} associated with the modulation frequencies f₁-f_{N} are independent from the time-variant input power P_{IN}(t).

Next, a reference modulation frequency f_{REF} among the modulation frequencies f₁-f_{N} is chosen and a set of linearized gain error correction terms is defined for the reference modulation frequency f_{REF}. In a non-limiting example, the reference modulation frequency f_{REF} can be a center modulation frequency among the modulation frequencies f₁-f_{N}.

Subsequently, a respective one of the linearized gain errors LG_{ERR-f1}-LG_{ERR-fN} of any selected one of the modulation frequencies f₁-f_{N} can be superimposed onto the respective linearized gain error LG_{ERR-fREF} of the reference modulation frequency f_{REF}. Herein, the phrase “superimposing” refers to a process for determining an appropriate x-axis shift (e.g., a vector) to align the respective one of the linearized gain errors LG_{ERR-f1}-LG_{ERR-fN} of any selected one of the modulation frequencies f₁-f_{N} with the respective linearized gain error LG_{ERR-fREF} of the reference modulation frequency f_{REF}.

As shown in FIG. 4, superimposing the linearized gain error LG_{ERR-f1} of the modulation frequency f₁ onto the linearized gain error LG_{ERR-fREF} of the reference modulation frequency f_{REF} is equivalent to shifting the linearized gain error LG_{ERR-f1} of the modulation frequency f₁ rightward along the x-axis. Likewise, superimposing the linearized gain error LG_{ERR-fN} of the modulation frequency f_{N} onto the linearized gain error LG_{ERR-fREF} of the reference modulation frequency fREF is equivalent to shifting the linearized gain error LG_{ERR-fN} of the modulation frequency f_{N} leftward along the x-axis. By superimposing the respective one of the linearized gain errors LG_{ERR-f1}-LG_{ERR-fN} of each of the modulation frequencies f₁-f_{N} onto the linearized gain error LG_{ERR-fREF} of the reference modulation frequency f_{REF}, it is possible to determine a respective linearized gain error correction term for each of the modulation frequencies f₁-f_{N} based on the set of linearized gain error correction terms defined for the reference modulation frequency f_{REF}. In this regard, the complexity associated with AM-AM error correction only revolves around the reference modulation frequency f_{REF}, as opposed to having to involve all the modulation frequencies f₁-f_{N}. As a result, the low-complexity AM-AM error correction scheme is clearly advantageous over the conventional methods where complicated mDPD coefficients must be defined and calibrated for each of the modulation frequencies f₁-f_{N}.

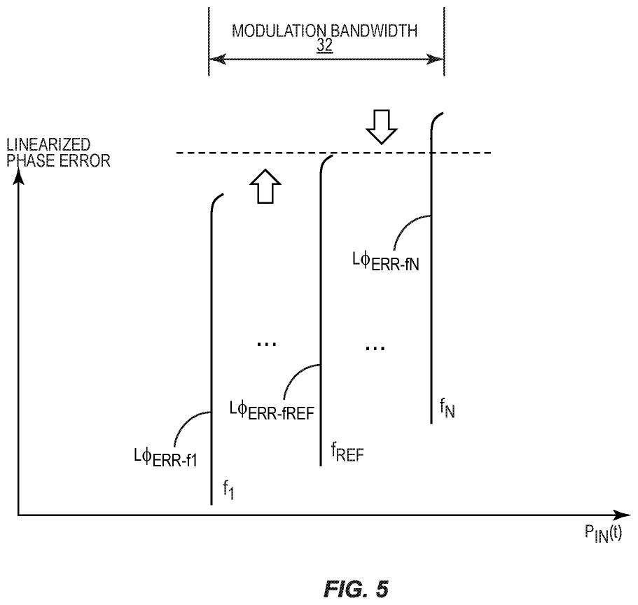

FIG. 5 is a graphic diagram illustrating a low-complexity AM-PM error correction scheme that can effectively correct the AM-PM error in the wireless communication circuit 10 of FIG. 1. Herein, the low-complexity AM-PM correction scheme is able to reduce complexity associated with AM-PM error correction by eliminating modulation frequency dependency of the phase error.

First of all, the phase error associated with each of the modulation frequencies f₁-f_{N} is linearized with respect to the time-variant input power P_{IN}(t) to create a respective one of multiple linearized phase errors Lϕ_{ERR-f1}-Lϕ_{ERR-fN}. As shown in FIG. 5, the linearized phase errors Lϕ_{ERR-f1}-Lϕ_{ERR-fN} associated with the modulation frequencies f₁-f_{N} are independent from the time-variant input power P_{IN}(t).

Next, a reference modulation frequency f_{REF} among the modulation frequencies f₁-f_{N} is chosen and a set of linearized phase error correction terms is defined for the reference modulation frequency f_{REF}. In a non-limiting example, the reference modulation frequency f_{REF} can be a center modulation frequency among the modulation frequencies f₁-f_{N}.

Subsequently, a respective one of the linearized phase errors Lϕ_{ERR-f1}-Lϕ_{ERR-fN} of any selected one of the modulation frequencies f₁-f_{N} can be superimposed onto the respective linearized phase error Lϕ_{ERR-fREF} of the reference modulation frequency f_{REF}. Herein, the phrase “superimposing” refers to a process for determining an appropriate y-axis shift (e.g., a vector) to align the respective one of the linearized phase errors Lϕ_{ERR-f1}-Lϕ_{ERR-fN} of any selected one of the modulation frequencies f₁-f_{N} with the respective linearized phase error Lϕ_{ERR-fREF} of the reference modulation frequency f_{REF}.

As shown in FIG. 5, superimposing the linearized phase error Lϕ_{ERR-f1} of the modulation frequency f₁ onto the linearized phase error Lϕ_{ERR-fREF} of the reference modulation frequency f_{REF} is equivalent to shifting the linearized phase error Lϕ_{ERR-f1} of the modulation frequency f₁ upward along the y-axis. Likewise, superimposing the linearized phase error Lϕ_{ERR-fN} of the modulation frequency f_{N} onto the linearized phase error Lϕ_{ERR-fREF} of the reference modulation frequency fREF is equivalent to shifting the linearized phase error Lϕ_{ERR-fN} of the modulation frequency f_{N} downward along the y-axis. By superimposing the respective one of the linearized phase errors Lϕ_{ERR-f1}-Lϕ_{ERR-fN} of each of the modulation frequencies f₁-f_{N} onto the linearized phase error Lϕ_{ERR-fREF} of the reference modulation frequency f_{REF}, it is possible to determine a respective linearized phase error correction term for each of the modulation frequencies f₁-f_{N} based on the set of linearized phase error correction terms defined for the reference modulation frequency f_{REF}. In this regard, the complexity associated with AM-PM error correction only revolves around the reference modulation frequency f_{REF}, as opposed to having to involve all the modulation frequencies f₁-f_{N}. As a result, the low-complexity AM-PM error correction scheme is clearly advantageous over the conventional methods where complicated mDPD coefficients must be defined and calibrated for each of the modulation frequencies f₁-f_{N}.

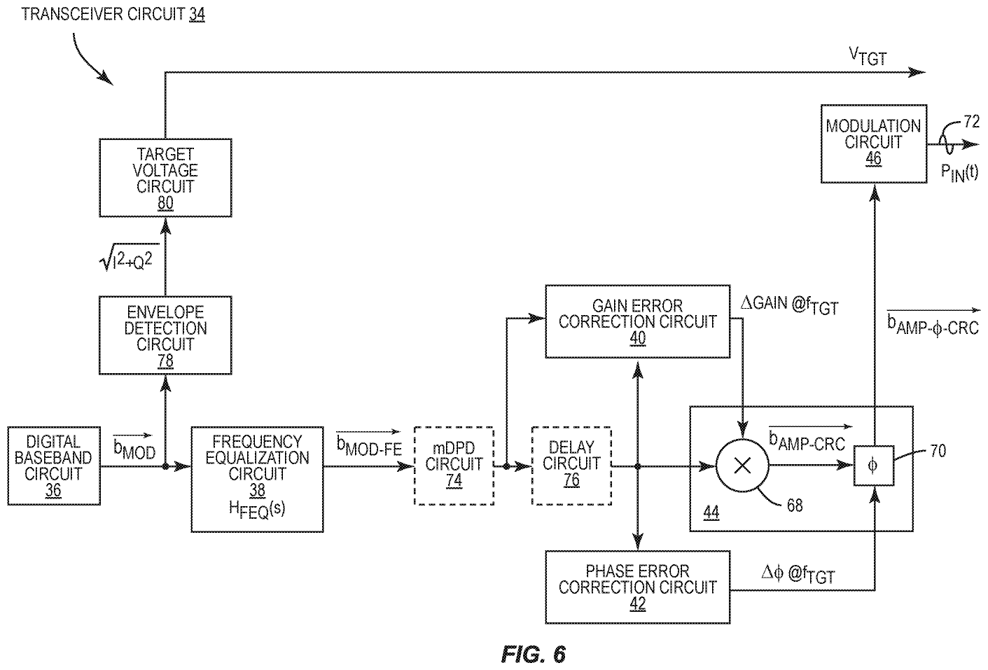

FIG. 6 is a schematic diagram of an exemplary transceiver circuit 34 configured according to embodiments of the present disclosure to correct the AM-AM and AM-PM errors in the wireless communication circuit 10 based on the low-complexity AM-AM error correction scheme in FIG. 4 and the low-complexity AM-PM error correction scheme in FIG. 5. In an embodiment, the transceiver circuit 34 can be provided in the wireless communication circuit 10 to replace the transceiver circuit 16. By replacing the transceiver circuit 16 with the transceiver circuit 34, the wireless communication circuit 10 can be adapted to support the low-complexity AM-AM and AM-PM error correction schemes of the present disclosure.

The transceiver circuit 34 includes a digital baseband circuit 36, a frequency equalization circuit 38, a gain error correction circuit 40, a phase error correction circuit 42, an amplitude-phase correction circuit 44, and a modulation circuit 46. The digital baseband circuit 36 is configured to generate an input vector \vec{b_{MOD}} in a selected modulation frequency f_{TGT} among the modulation frequencies f₁-f_{N} across the modulation bandwidth 32 (f_{TGT}∈(f₁-f_{N})).

The frequency equalization circuit 38 is configured to apply a frequency equalization filter H_{FEQ}(S) to the input vector \vec{b_{MOD}} to generate a frequency-equalized input vector \vec{b_{MOD-FE}}, in which each of the modulation frequencies f₁-f_{N} is associated with a respective one of the linearized gain errors LG_{ERR-f1}-LG_{ERR-fN} as illustrated in FIG. 4 and a respective one of the linearized phase errors LG_{ERR-f1}-LG_{ERR-fN} as illustrated in FIG. 5. As previously illustrated in FIGS. 4 and 5, the linearized gain errors LG_{ERR-f1}-LG_{ERR-fN} and the linearized phase errors LG_{ERR-f1}-LG_{ERR-fN} are independent from the time-variant input power P_{IN}(t) across the modulation frequencies f₁-f_{N} in the modulation bandwidth 32.

The gain error correction circuit 40 is configured to determine a linearized gain error correction term ΔGain in the selected modulation frequency f_{TGT} among the modulation frequencies f₁-f_{N} based on the respective linearized gain error LG_{ERR-fREF} (LG_{ERR-fREF}∈(LG_{ERR-f1}-LG_{ERR-fN})) in a reference modulation frequency f_{REF} selected among the modulation frequencies f₁-f_{N} (fREF E (f₁-f_{N})). The phase error correction circuit 42 is configured to determine a linearized phase error correction term Δϕ in the selected modulation frequency f_{TGT} based on the respective linearized phase error Lϕ_{ERR-fREF} (Lϕ_{ERR-fREF}∈(Lϕ_{ERR-f1}-Lϕ_{ERR-fN})) in the reference modulation frequency f_{REF}. The amplitude-phase correction circuit 44 is configured to add the linearized gain error correction term ΔGain and the linearized phase error correction term Δϕ to the frequency-equalized input vector \vec{b_{MOD-FE}} to thereby generate an amplitude-phase corrected input vector \vec{b_{AMP-ϕ-CRC}} in the selected modulation frequency f_{TGT}.

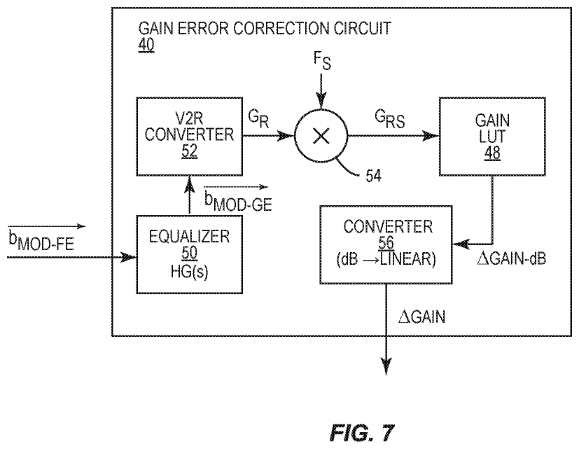

FIG. 7 is a schematic diagram providing an exemplary illustration of the gain error correction circuit 40 in the transceiver circuit 34 of FIG. 6. Common elements between FIGS. 6 and 7 are shown therein with common element numbers and will not be re-described herein.

In an embodiment, the gain error correction circuit 40 includes a gain lookup table (LUT) circuit 48, which may be preprogrammed to store a set of decibel gain error correction terms ΔGain-dB associated with the reference modulation frequency f_{REF}. As previously described in FIG. 4, each of the modulation frequencies f₁-f_{N} can be superimposed on the reference modulation frequency f_{REF} by shifting a respective one of the modulation frequencies f₁-f_{N} leftward or rightward. In this regard, in a non-limiting example, the gain LUT circuit 48 can be programmed to correlate different amounts of the leftward or rightward shift with different decibel gain error correction terms ΔGain-dB. As such, once the amount of the leftward or rightward shift associated with a respective one of the modulation frequencies f₁-f_{N} is determined, the gain LUT circuit 48 will be able to provide a corresponding decibel gain error correction term ΔGain-dB for the respective one of the modulation frequencies f₁-f_{N}.

The gain error correction circuit 40 also includes a gain equalizer circuit 50, a gain vector-to-real (V2R) converter 52, a gain scaler 54 (e.g., a digital scaler), and a converter circuit 56. The gain equalizer circuit 50 is configured to apply a complex gain filter HG(s) to the frequency-equalized input vector \vec{b_{MOD-FE}} to generate a gain-equalized input vector \vec{b_{MOD-GE}} wherein the respective one of the linearized gain errors LG_{ERR-f1}-LG_{ERR-fN} in the selected one of the modulation frequencies f₁-f_{N} is superimposed onto the respective linearized gain error LG_{ERR-fREF} in the reference modulation frequency f_{REF}.

The gain V2R converter 52 is configured to extract a real gain parameter G_{R} from the gain-equalized input vector \vec{b_{MOD-GE}}. The gain scaler 54 may be configured to scale the real gain parameter G_{R} based on a scaling factor F_{S} to generate a scaled real gain parameter G_{RS}. According to an embodiment of the present disclosure, the scaled real gain parameter G_{RS} represents an amount of leftward (e.g., a negative number) or rightward (e.g., a positive number) shift that is required to superimpose the respective one of the linearized gain errors LG_{ERR-f1}-LG_{ERR-fN} of the selected one of the modulation frequencies f₁-f_{N} onto the linearized gain error LG_{ERR-fREF} of the reference modulation frequency fREF.

Based on the scaled real parameter G_{RS}, the gain LUT circuit 48 is able to determine a corresponding decibel gain error correction term ΔGain-dB in the reference modulation frequency f_{REF}. The converter circuit 56 then converts the decibel gain error correction term ΔGain-dB into the linearized gain error correction term ΔGain for the selected one of the modulation frequencies f₁-f_{N}.

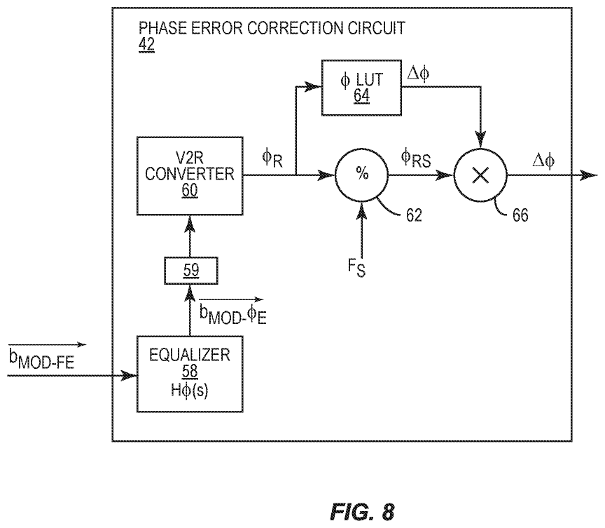

FIG. 8 is a schematic diagram providing an exemplary illustration of the phase error correction circuit 42 in the transceiver circuit 34 of FIG. 6. Common elements between FIGS. 6 and 8 are shown therein with common element numbers and will not be re-described herein.

In an embodiment, the phase error correction circuit 42 includes a phase equalizer circuit 58, an amplitude calculator 59, a phase V2R converter 60, a phase scaler 62, a phase LUT 64, and a phase multiplier 66. The phase equalizer circuit 58 is configured to apply a complex phase filter Hϕ(s) to the frequency-equalized input vector \vec{b_{MOD-FE}} to generate a phase-equalized input vector \vec{b_{MOD-ϕE}} wherein the respective one of the linearized phase errors Lϕ_{ERR-f1}-Lϕ_{ERR-fN} in the selected one of the modulation frequencies f₁-f_{N} is superimposed onto the respective linearized phase error Lϕ_{ERR-fREF} in the reference modulation frequency f_{REF}. The amplitude calculator 59 is configured to calculate an amplitude of the phase-equalized input vector \vec{b_{MOD-ϕE}}.

The phase V2R converter 60 is configured to extract a real phase parameter OR from the phase-equalized input vector \vec{b_{MOD-ϕE}}. The phase scaler 62 is configured to scale the real phase parameter OR to generate a scaled real phase parameter ϕ_{RS}. The phase LUT circuit 64 is configured to determine the linearized gain error correction term Δϕ in the reference modulation frequency fREF based on the real phase parameter OR. The phase multiplier 66 is configured to multiply the scaled real phase parameter ϕ_{RS} with the linearized gain error correction term Δϕ.

With reference back to FIG. 6, the amplitude-phase correction circuit 44 includes a multiplier circuit 68 and a phase shifter 70. The multiplier circuit 68 is configured to multiply the linearized gain error correction term ΔGain with the frequency-equalized input vector \vec{b_{MOD-FE}} to thereby generate an amplitude-corrected input vector \vec{b_{AMP-CRC}}. The phase shifter 70 is configured to apply the linearized phase error correction term Δϕ to the amplitude-corrected input vector \vec{b_{AMP-CRC}} to thereby generate an amplitude-phase corrected input vector \vec{b_{AMP-ϕ-CRC}}. Subsequently, the modulation circuit 46 can convert the amplitude-phase corrected input vector \vec{b_{AMP-ϕ-CRC}} into an RF signal 72 and modulate the RF signal 72 onto an intermediate frequency (IF) or a carrier frequency.

The transceiver circuit 34 may include an mDPD circuit 74. In an embodiment, the mDPD circuit 74 can be configured to correct any residual gain error in the gain-equalized input vector \vec{b_{MOD-GE}} (as shown in FIG. 7). The transceiver circuit 34 may also include a delay circuit 76, which can be configured to delay the frequency-equalized input vector \vec{b_{MOD-FE}} to compensate for a group delay associated with the gain error correction circuit 40 and/or the phase error correction circuit 42.

The transceiver circuit 34 further includes an envelope detection circuit 78 and a target voltage circuit 80. The envelope detection circuit 78 is configured to detect a time-variant amplitude envelope \sqrt{I²+Q²} of the input vector \vec{b_{MOD}}, wherein “I” and “Q” represent an in-phase component and a quadrature component of the input vector \vec{b_{MOD}}, respectively. The target voltage circuit 80 is configured to generate a time-variant target voltage VTGT that keeps track of the time-variant amplitude envelope \sqrt{I²+Q²} of the input vector \vec{b_{MOD}}.

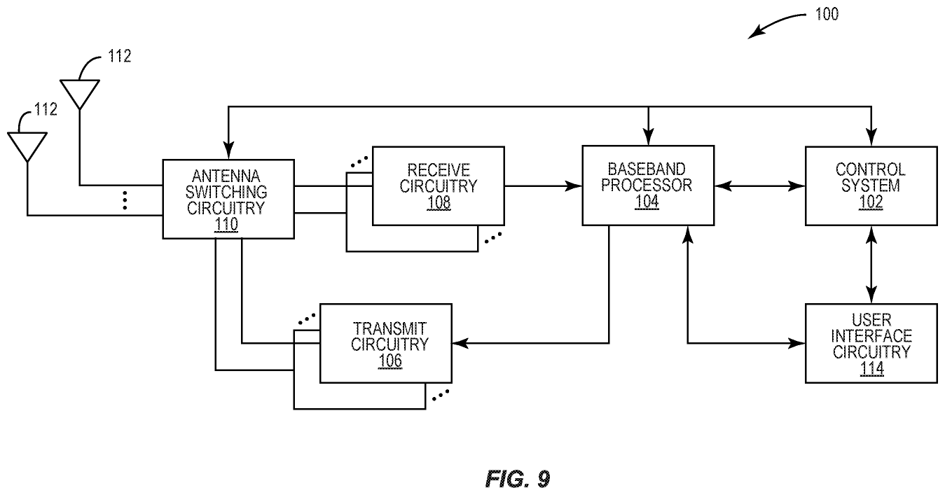

The transceiver circuit 34 of FIG. 6 can be provided in a user element (a.k.a. wireless device) to support the embodiments described above. In this regard, FIG. 9 is a schematic diagram of an exemplary user element 100 wherein the transceiver circuit 34 of FIG. 6 can be provided.

Herein, the user element 100 can be any type of user elements, such as mobile terminals, smart watches, tablets, computers, navigation devices, access points, and like wireless communication devices that support wireless communications, such as cellular, wireless local area network (WLAN), Bluetooth, and near field communications. The user element 100 will generally include a control system 102, a baseband processor 104, transmit circuitry 106, receive circuitry 108, antenna switching circuitry 110, multiple antennas 112, and user interface circuitry 114. In a non-limiting example, the control system 102 can be a field-programmable gate array (FPGA), as an example. In this regard, the control system 102 can include at least a microprocessor(s), an embedded memory circuit(s), and a communication bus interface(s). The receive circuitry 108 receives radio frequency signals via the antennas 112 and through the antenna switching circuitry 110 from one or more base stations. A low noise amplifier and a filter cooperate to amplify and remove broadband interference from the received signal for processing. Downconversion and digitization circuitry (not shown) will then downconvert the filtered, received signal to an intermediate or baseband frequency signal, which is then digitized into one or more digital streams using analog-to-digital converter(s) (ADC).

The baseband processor 104 processes the digitized received signal to extract the information or data bits conveyed in the received signal. This processing typically comprises demodulation, decoding, and error correction operations, as will be discussed in greater detail below. The baseband processor 104 is generally implemented in one or more digital signal processors (DSPs) and application specific integrated circuits (ASICs).

For transmission, the baseband processor 104 receives digitized data, which may represent voice, data, or control information, from the control system 102, which it encodes for transmission. The encoded data is output to the transmit circuitry 106, where a digital-to-analog converter(s) (DAC) converts the digitally encoded data into an analog signal and a modulator modulates the analog signal onto a carrier signal that is at a desired transmit frequency or frequencies. A power amplifier will amplify the modulated carrier signal to a level appropriate for transmission, and deliver the modulated carrier signal to the antennas 112 through the antenna switching circuitry 110. The multiple antennas 112 and the replicated transmit and receive circuitries 106, 108 may provide spatial diversity. Modulation and processing details will be understood by those skilled in the art.

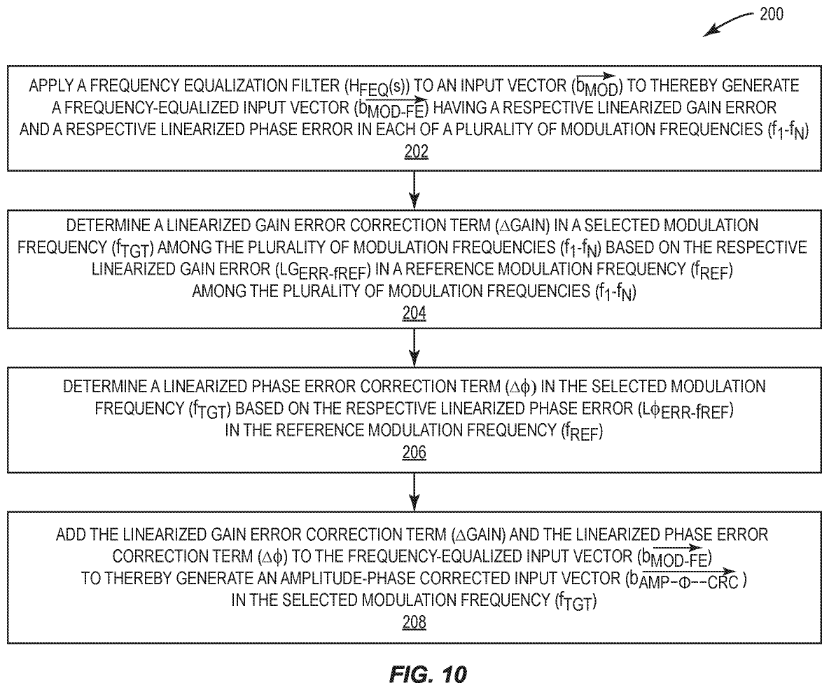

In an embodiment, the user equipment 100 of FIG. 9 can be configured to correct amplitude and phase errors according to a process. In this regard, FIG. 10 is a flowchart of an exemplary process 200 for correcting amplitude and phase errors in a wireless communication circuit, such as the user element 100 of FIG. 9.

Herein, the process 200 includes applying the frequency equalization filter H_{FEQ}(S) to the input vector \vec{b_{MOD}} to thereby generate the frequency-equalized input vector \vec{b_{MOD-FE}} having the respective linearized gain error and the respective linearized phase error in each of the modulation frequencies f₁-f_{N} (step 202). The process 200 also includes determining the linearized gain error correction term ΔGain in the selected modulation frequency f_{TGT} among the modulation frequencies f₁-f_{N} based on the respective linearized gain error LG_{ERR-fREF} in the reference modulation frequency f_{REF} among the modulation frequencies f₁-f_{N} (step 204). The process 200 also includes determining the linearized phase error correction term Δϕ in the selected modulation frequency f_{TGT} based on the respective linearized phase error Lϕ_{ERR-fREF} in the reference modulation frequency f_{REF} (step 206). The process 200 also includes adding the linearized gain error correction term ΔGain and the linearized phase error correction term Δϕ to the frequency-equalized input vector \vec{b_{MOD-FE}} to thereby generate the amplitude-phase corrected input vector \vec{b_{AMP-ϕ-CRC}} in the selected modulation frequency f_{TGT} (step 208).

Those skilled in the art will recognize improvements and modifications to the preferred embodiments of the present disclosure. All such improvements and modifications are considered within the scope of the concepts disclosed herein and the claims that follow.

What is claimed is:

1. A transceiver circuit comprising:
a frequency equalization circuit configured to apply a frequency equalization filter to an input vector to thereby generate a frequency-equalized input vector having a respective linearized gain error and a respective linearized phase error in each of a plurality of modulation frequencies;
a gain error correction circuit configured to determine a linearized gain error correction term in a selected modulation frequency among the plurality of modulation frequencies based on the respective linearized gain error in a reference modulation frequency among the plurality of modulation frequencies;
a phase error correction circuit configured to determine a linearized phase error correction term in the selected modulation frequency based on the respective linearized phase error in the reference modulation frequency; and
an amplitude-phase correction circuit configured to add the linearized gain error correction term and the linearized phase error correction term to the frequency-equalized input vector to thereby generate an amplitude-phase corrected input vector in the selected modulation frequency.

2. The transceiver circuit of claim 1, wherein the gain error correction circuit is further configured to:
apply a complex gain filter to the frequency-equalized input vector to superimpose the respective linearized gain error in the selected modulation frequency onto the respective linearized gain error in the reference modulation frequency; and
determine the linearized gain error correction term in the selected modulation frequency based on the respective linearized gain error in the reference modulation frequency.

3. The transceiver circuit of claim 2, wherein the gain error correction circuit comprises:
a gain equalizer circuit configured to apply the complex gain filter to the frequency-equalized input vector to superimpose the respective linearized gain error in the selected modulation frequency onto the respective linearized gain error in the reference modulation frequency to thereby generate a gain-equalized input vector;
a gain vector-to-real (V2R) converter configured to extract a real gain parameter from the gain-equalized input vector;
a gain scaler configured to scale the real gain parameter to generate a scaled real gain parameter;
a gain lookup table (LUT) circuit configured to determine a decibel gain error correction term in the reference modulation frequency based on the scaled real gain parameter; and
a converter circuit configured to convert the decibel gain error correction term into the linearized gain error correction term.

4. The transceiver circuit of claim 1, wherein the phase error correction circuit is further configured to:
apply a complex phase filter to the frequency-equalized input vector to superimpose the respective linearized phase error in the selected modulation frequency onto the respective linearized phase error in the reference modulation frequency; and
determine the linearized phase error correction term in the selected modulation frequency based on the respective linearized phase error in the reference modulation frequency.

5. The transceiver circuit of claim 4, wherein the gain error correction circuit comprises:
a phase equalizer circuit configured to apply the complex phase filter to the frequency-equalized input vector to superimpose the respective linearized phase error in the selected modulation frequency onto the respective linearized phase error in the reference modulation frequency to thereby generate a phase-equalized input vector;
an amplitude calculator configured to calculate an amplitude of the phase-equalized input vector;
a phase vector-to-real (V2R) converter configured to extract a real phase parameter from the phase-equalized input vector;
a phase scaler configured to scale the real phase parameter to generate a scaled real phase parameter;
a phase lookup table (LUT) circuit configured to determine the linearized phase error correction term in the reference modulation frequency based on the real phase parameter; and
a phase multiplier configured to multiply the scaled real phase parameter with the linearized gain error correction term.

6. The transceiver circuit of claim 1, wherein the amplitude-phase correction circuit comprises:
a multiplier circuit configured to multiply the linearized gain error correction term with the frequency-equalized input vector to thereby generate an amplitude-corrected input vector; and
a phase shifter configured to apply the linearized phase error correction term to the amplitude-corrected input vector to thereby generate the amplitude-phase corrected input vector.

7. The transceiver circuit of claim 1, further comprising a digital baseband circuit configured to generate the input vector in the selected modulation frequency.

8. The transceiver circuit of claim 1, further comprising a modulation circuit configured to convert the amplitude-phase corrected input vector into a radio frequency (RF) signal and modulate the RF signal onto an intermediate frequency or a carrier frequency.

9. The transceiver circuit of claim 1, further comprising a memory digital predistortion (mDPD) circuit configured to correct a residual gain error in the frequency-equalized input vector.

10. The transceiver circuit of claim 1, further comprising a delay circuit configured to delay the frequency-equalized input vector to compensate for a group delay associated with the gain error correction circuit and/or the phase error correction circuit.

11. The transceiver circuit of claim 1, wherein the reference modulation frequency is a center modulation frequency among the plurality of modulation frequencies.

12. A wireless device comprising a transceiver circuit comprising:
a frequency equalization circuit configured to apply a frequency equalization filter to an input vector to thereby generate a frequency-equalized input vector having a respective linearized gain error and a respective linearized phase error in each of a plurality of modulation frequencies;
a gain error correction circuit configured to determine a linearized gain error correction term in a selected modulation frequency among the plurality of modulation frequencies based on the respective linearized gain error in a reference modulation frequency among the plurality of modulation frequencies;
a phase error correction circuit configured to determine a linearized phase error correction term in the selected modulation frequency based on the respective linearized phase error in the reference modulation frequency; and
an amplitude-phase correction circuit configured to add the linearized gain error correction term and the linearized phase error correction term to the frequency-equalized input vector to thereby generate an amplitude-phase corrected input vector in the selected modulation frequency.

13. The wireless device of claim 12, wherein the gain error correction circuit is further configured to:
apply a complex gain filter to the frequency-equalized input vector to superimpose the respective linearized gain error in the selected modulation frequency onto the respective linearized gain error in the reference modulation frequency; and
determine the linearized gain error correction term in the selected modulation frequency based on the respective linearized gain error in the reference modulation frequency.

14. The wireless device of claim 13, wherein the gain error correction circuit comprises:
a gain equalizer circuit configured to apply the complex gain filter to the frequency-equalized input vector to superimpose the respective linearized gain error in the selected modulation frequency onto the respective linearized gain error in the reference modulation frequency to thereby generate a gain-equalized input vector;
a gain vector-to-real (V2R) converter configured to extract a real gain parameter from the gain-equalized input vector;
a gain scaler configured to scale the real gain parameter to generate a scaled real gain parameter;
a gain lookup table (LUT) circuit configured to determine a decibel gain error correction term in the reference modulation frequency based on the scaled real gain parameter; and
a converter circuit configured to convert the decibel gain error correction term into the linearized gain error correction term.

15. The wireless device of claim 12, wherein the phase error correction circuit is further configured to:
apply a complex phase filter to the frequency-equalized input vector to superimpose the respective linearized phase error in the selected modulation frequency onto the respective linearized phase error in the reference modulation frequency; and
determine the linearized phase error correction term in the selected modulation frequency based on the respective linearized phase error in the reference modulation frequency.

16. The wireless device of claim 15, wherein the gain error correction circuit comprises:
a phase equalizer circuit configured to apply the complex phase filter to the frequency-equalized input vector to superimpose the respective linearized phase error in the selected modulation frequency onto the respective linearized phase error in the reference modulation frequency to thereby generate a phase-equalized input vector;
an amplitude calculator configured to calculate an amplitude of the phase-equalized input vector;
a phase vector-to-real (V2R) converter configured to extract a real phase parameter from the phase-equalized input vector;
a phase scaler configured to scale the real phase parameter to generate a scaled real phase parameter;
a phase lookup table (LUT) circuit configured to determine the linearized phase error correction term in the reference modulation frequency based on the real phase parameter; and
a phase multiplier configured to multiply the scaled real phase parameter with the linearized gain error correction term.

17. The wireless device of claim 12, wherein the amplitude-phase correction circuit comprises:
a multiplier circuit configured to multiply the linearized gain error correction term with the frequency-equalized input vector to thereby generate an amplitude-corrected input vector; and
a phase shifter configured to apply the linearized phase error correction term to the amplitude-corrected input vector to thereby generate the amplitude-phase corrected input vector.

18. The wireless device of claim 12, wherein the transceiver circuit further comprises:
a digital baseband circuit configured to generate the input vector in the selected modulation frequency;
a modulation circuit configured to convert the amplitude-phase corrected input vector into a radio frequency (RF) signal and modulate the RF signal onto an intermediate frequency or a carrier frequency;
a memory digital predistortion (mDPD) circuit configured to correct a residual gain error in the frequency-equalized input vector; and
a delay circuit configured to delay the frequency-equalized input vector to compensate for a group delay associated with the gain error correction circuit and/or the phase error correction circuit.

19. The wireless device of claim 18, wherein the transceiver circuit further comprises:
an envelope detection circuit configured to detect a time-variant amplitude envelope of the input vector; and
a target voltage circuit configured to generate a time-variant target voltage that keeps track of the time-variant amplitude envelope of the input vector.

20. A method for correcting amplitude and phase errors in a wireless communication circuit comprising:
applying a frequency equalization filter to an input vector to thereby generate a frequency-equalized input vector having a respective linearized gain error and a respective linearized phase error in each of a plurality of modulation frequencies;
determining a linearized gain error correction term in a selected modulation frequency among the plurality of modulation frequencies based on the respective linearized gain error in a reference modulation frequency among the plurality of modulation frequencies;
determining a linearized phase error correction term in the selected modulation frequency based on the respective linearized phase error in the reference modulation frequency; and
adding the linearized gain error correction term and the linearized phase error correction term to the frequency-equalized input vector to thereby generate an amplitude-phase corrected input vector in the selected modulation frequency.
